(19) United States
(12) Patent Application Publication
(10) Pub. No.: US 2026/0118772 A1
(43) Pub. Date: Apr. 30, 2026

(54) OPC METHOD AND METHOD FOR MANUFACTURING SEMICONDUCTOR DEVICE USING THE SAME

(71) Applicant: Samsung Electronics Co., Ltd., Suwon-si (KR)

(72) Inventors: Seonyeop KIM, Suwon-si (KR); Wangi SOHN, Suwon-si (KR); Junyoung JANG, Suwon-si (KR)

(73) Assignee: Samsung Electronics Co., Ltd., Suwon-si (KR)

(21) Appl. No.: 19/269,184

(22) Filed: Jul. 15, 2025

(30) Foreign Application Priority Data
Oct. 31, 2024 (KR) 10-2024-0152788

(51) Int. Cl. G03F 7/00; G03F 1/36; H01L 21/283; H01L 21/308

(52) U.S. Cl. CPC G03F 7/70441; G03F 1/36; G03F 7/70508; H10P 14/40; H10P 50/691

(57) ABSTRACT

Provided is a method for manufacturing a semiconductor device including performing optical proximity correction on a layout. The optical proximity correction includes generating a contour of a target pattern of the layout, generating first to fourth error vectors between the contour and first to fourth edge segments of the target pattern, and generating a correction pattern by sequentially performing a first correction and a second correction on the target pattern. The first correction includes moving the first edge segment on the basis of the first error vector, and moving the second edge segment on the basis of the second error vector. The second correction includes moving the third and fourth edge segments on the basis of a sum of the third error vector and the fourth error vector. The first and second edge segments face each other, and the third and fourth edge segment face each other.

### CROSS-REFERENCE TO RELATED APPLICATIONS

This U.S. non-provisional patent application claims priority under 35 U.S.C. § 119 of Korean Patent Application No. 10-2024-0152788, filed on Oct. 31, 2024, the entire contents of which are hereby incorporated by reference.

### BACKGROUND

Some example embodiments relate to a method for manufacturing a semiconductor device, and more particularly, to a method for manufacturing a semiconductor device using an optical proximity correction (OPC) method.

A semiconductor device is attracting attention as an important component in the electronics industry due to characteristics thereof such as miniaturization, multi-functionality, and/or low manufacturing cost. The semiconductor devices may be classified into a semiconductor memory device that stores a logical data, a semiconductor logic device that calculates and processes the logical data, and a hybrid semiconductor device that includes a memory component and a logic component. As the electronics industry highly develops, a desire for the characteristics of the semiconductor device is gradually increasing. For example, a desire for high reliability, high speed and/or multi-functionality of the semiconductor device is gradually increasing. A structure in the semiconductor device gradually becomes more complicated so as to satisfy the expectations for such characteristics, and the semiconductor device is gradually highly integrated.

### SUMMARY

Some example embodiments may provide an OPC method for forming correction patterns having small distribution in a layout.

Alternatively or additionally, some example embodiments may provide a method for manufacturing a semiconductor device with improved reliability.

Technical goals of inventive concepts are not limited to the goal mentioned above, and other technical goals that are not mentioned may be clearly understood from description below by those of ordinary skill in the art.

Some example embodiments may provide a method for manufacturing a semiconductor device including performing optical proximity correction on a layout, and forming a photoresist pattern on a substrate using a photomask manufactured with the corrected layout. The optical proximity correction includes generating a contour of a target pattern of the layout, generating first to fourth error vectors between the contour and first to fourth edge segments of the target pattern, and generating a correction pattern by sequentially performing a first correction and a second correction on the target pattern. The first correction includes moving the first edge segment on the basis of the first error vector, and moving the second edge segment on the basis of the second error vector. The second correction includes moving the third and fourth edge segments on the basis of a sum of the third error vector and the fourth error vector. The first and second edge segments face each other, and the third and fourth edge segment face each other.

Alternatively or additionally, a method for manufacturing a semiconductor device may include performing optical proximity correction on a layout, and forming a photoresist pattern on a substrate using a photomask manufactured with the corrected layout. The optical proximity correction includes generating a contour of a target pattern of the layout, generating first to fourth error vectors between the contour and first to fourth edge segments of the target pattern, generating a correction pattern by sequentially performing a first correction on each of the first and second edge segments facing each other, and a second correction on each of the third and fourth edge segments facing each other, and setting a first long-short-ratio of the correction pattern. The second correction includes moving the third and fourth edge segments on the basis of a sum of the third error vector and the fourth error vector, and fitting the first long-short-ratio of the correction pattern by additionally moving the third and fourth edge segments.

Alternatively or additionally according to some example embodiments, a method for manufacturing a semiconductor device may include generating a contour of a target pattern of a layout, generating first to fourth error vectors between the contour and first to fourth edge segments of the target pattern, generating a correction pattern by sequentially performing a first correction and a second correction on the target pattern, manufacturing a photomask using the corrected layout including the correction pattern, forming an etching target layer and a photoresist layer on a substrate, forming photoresist patterns by exposing and developing the photoresist layer using the photomask, and patterning the etching target layer using the photoresist patterns. The first correction includes moving the first edge segment on the basis of the first error vector, and moving the second edge segment facing the first edge segment on the basis of the second error vector, and the second correction includes moving the third and fourth edge segments facing each other on the basis of a sum of the third error vector and the fourth error vector.

Alternatively or additionally according to some example embodiments, there is provided a system including at least one processor, and a memory storing non-transitory computer-readable medium storing instructions that, when executed on the at least one processor, cause the system to provision a layout of a layer in a semiconductor device, generate a contour of a target pattern of the layout, generate first to fourth error vectors between the contour and first to fourth edge segments of the target pattern, and generate a correction pattern by sequentially performing a first correction and a second correction on the target pattern. The first correction includes moving the first edge segment on the basis of the first error vector, and moving the second edge segment on the basis of the second error vector, the second correction includes moving the third and fourth edge segments on the basis of a sum of the third error vector and the fourth error vector, the first and second edge segments face each other, and the third and fourth edge segments face each other.

According to some example embodiments, the first and second edge segments extend in a first direction, and the third and fourth edge segments extend in a second direction crossing the first direction.

According to some example embodiments, the processor is further configured to set a first long-short-ratio of the correction pattern. The second correction further includes additionally moving the third and fourth edge segments to fit the first long-short-ratio of the correction pattern.

### BRIEF DESCRIPTION OF THE FIGURES

The accompanying drawings are included to provide a further understanding of inventive concepts, and are incorporated in and constitute a part of this specification. The drawings illustrate some example embodiments of inventive concepts and, together with the description, serve to explain certain principles of inventive concepts. In the drawings:

FIG. 1 is a block diagram illustrating a computer system for designing a semiconductor according to some example embodiments;

FIG. 2 is a flowchart illustrating a method for designing and manufacturing a semiconductor device according to some example embodiments;

FIG. 3 is a conceptual diagram illustrating a photolithography system using a photomask manufactured according to some example embodiments;

FIGS. 4A, 4B, and 4C are flowcharts schematically illustrating specific operations of optical proximity correction according to some example embodiments, respectively;

FIGS. 5 to 11 are plan views of a layout for describing optical proximity correction, respectively;

FIG. 12 is a plan view illustrating a photomask according to some example embodiments;

FIG. 13 is a conceptual diagram illustrating formation of photoresist patterns on a substrate using a photomask of FIG. 12; and

FIGS. 14 to 21 are diagrams illustrating a method for manufacturing a semiconductor device according to some example embodiments.

### DETAILED DESCRIPTION

Some example embodiments will be described in more detail with reference to the accompanying drawings so as to more specifically describe inventive concepts.

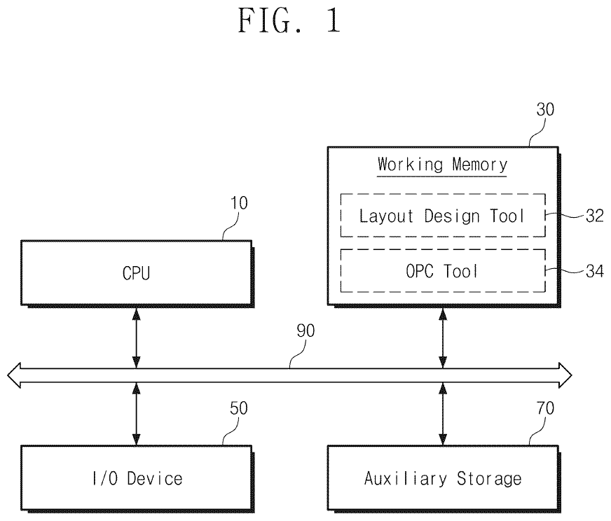

FIG. 1 is a block diagram illustrating a computer system for designing a semiconductor according to some example embodiments.

Referring to FIG. 1, the computer system may include a CPU 10, a working memory 30, an input-output device 50 and an auxiliary memory device 70. The computer system may be provided as a dedicated device for designing a layout according to some example embodiments; however, example embodiments are not limited thereto. The computer system may have various design and verification simulation programs.

The CPU 10 may execute software (one or more of an application program, an operation system, and device drives) performed in the computer system. The CPU 10 may execute the operation system (OS, not shown) loaded to the working memory 30. The CPU 10 may execute various application programs driven in the operation system (OS). For example, the CPU 10 may execute a layout design tool 32 and/or an OPC tool 34 loaded to the working memory 30. In some example embodiments, the CPU 10 may also execute other tools such as but not limited to a dummy fill tool and/or layout-versus-schematic (LVS) tool and/or a design-rule checking (DRC) tool; example embodiments are not limited thereto.

The operation system (OS) and/or application programs may be loaded to the working memory 30. When the computer system is booted, an OS image (not shown) stored in the auxiliary memory device 70 may be loaded to the working memory 30 according to a booting sequence. At least some of, or up to the entire input-output operations of the computer system may be supported by the operation system (OS). The application programs selected, e.g. by a user, or supplying a basic service may be loaded to the working memory 30. The layout design tool 32 and/or the OPC tool 34 may be loaded from the auxiliary memory device 70 to the working memory 30. As used herein, the term “user” may refer to one or more operators and/or a technicians. Alternatively or additionally, the term “user” may refer to an artificial intelligence (AI) model such as by a large language model (LLM).

The layout design tool 32 may have a bias function capable of changing shapes and positions of specific layout patterns to be different from what is defined by a design rule. Alternatively or additionally, the layout design tool 32 may perform design rule check (DRC) under the changed bias data condition. The OPC tool 34 may perform optical proximity correction (OPC) for the layout data output by the layout design tool 32. The working memory 30 may be or may include a volatile memory such as a static random access memory (SRAM) and/or a dynamic random access memory (DRAM), and/or an involatile memory such as one or more of a PRAM, an MRAM, a ReRAM, an FRAM, or a NOR flash memory.

The input-output device 50 controls user's input from and output to user interface devices. For example, the input-output device 50 may have a keyboard or monitor so that information is input from a designer. The designer may be or may include an operator; alternatively or additionally, the designer may be or may include an AI engine. The designer may receive, by using the input-output device 50, the information about a semiconductor region or data paths in which adjusted operation characteristics are required. A processing procedure, a processing result, or the like of the OPC tool 34 may be displayed through the input-output device 50.

The auxiliary memory device 70 is provided as a storage medium of the computer system. The auxiliary memory device 70 may store the application programs, an operation system image and various data. The auxiliary memory device 70 may alternatively or additionally be provided as a memory card (one or more of an MMC, an eMMC, an SD, a micro-SD, or the like), and/or a hard-disk drive (HDD). The auxiliary memory device 70 may include a NAND-type flash memory having a large storage capacity. Alternatively or additionally, the auxiliary memory device 70 may include a next-generation involatile memory such as one or more of a PRAM, an MRAM, an ReRAM, or an FRAM, or a NOR-type flash memory.

A system interconnector 90 may be a system bus for providing a network inside the computer system. The system interconnector 90 may be or may include a wired bus and/or a wireless bus; example embodiments are not limited thereto. The CPU 10, the working memory 30, the input-output device 50 and the auxiliary memory device 70 may be electrically connected to each other and mutually exchange a data through the system interconnector 90. However, configuration of the system interconnector 90 is not limited to only the description made above, and may further include intervention means for efficient management.

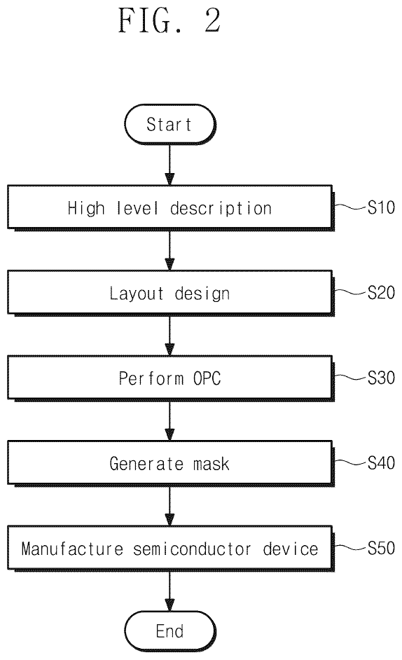

FIG. 2 is a flowchart illustrating a method for designing and manufacturing a semiconductor device according to some example embodiments.

Referring to FIG. 2, an operation (S10) of designing a semiconductor integrated circuit at a high level by using the computer system described with reference to FIG. 1 may be performed. Designing at a high level may mean writing an integrated circuit, which is a design object, in a higher level language among computer languages. For example, the higher level language such as C may be used. Alternatively or additionally, the higher level language may include one or more of Verilog or VHDL. Circuits designed by designing at the higher level design may be more specifically expressed by register transfer level (RTL) coding and/or simulation. In addition, a code generated by the register transfer level coding may be transferred to a netlist to be synthesized to an entire semiconductor device. A synthesized schematic circuit may be verified by a simulation tool, and an adjustment operation may be accompanied depending on a verification result.

An operation (S20) of designing a layout so as to realize a logically completed semiconductor integrated circuit on a silicon substrate may be performed. For example, designing the layout may be performed with reference to the schematic circuit synthesized by designing at the higher level and/or the netlist corresponding thereto, for example by preparing one or more layouts corresponding to one or more features to be patterned and/or etched and/or implanted on a substrate. Designing the layout may include a routing operation of placing and connecting various standard cells provided by a cell library according to a regulated design rule.

The cell library for designing the layout may include information about an operation, a speed, power consumption, and the like of a standard cell. The cell library for expressing a specific gate level circuit as the layout is defined in most of layout design tools. The layout may be or may include a procedure in which a shape or a size of a pattern for constituting a transistor and metal wires actually to be formed on or in a substrate is defined. The substrate may be a silicon substrate; however, example embodiments are not limited thereto. For example, layout patterns such as a PMOS, an NMOS, an N-well, a gate electrode, contacts, vias, and polysilicon and/or metal wires disposed thereon may be appropriately disposed so as to actually form an inverter circuit on the substrate. For this, first, a suitable inverter among the inverters already defined in the cell library may be searched and selected, e.g. by a user such as an operator and/or an A.I. engine.

Alternatively or additionally, the routing operation of the standard cells selected and disposed may be performed. Specifically, the routing operation of placing upper wires on and connecting the upper wires to the standard cells selected and disposed may be performed. The standard cells may be connected to each other so as to fit the design through the routing operation. Most of such a series of operations may be automatically or passively performed by the layout design tool. Alternatively or additionally, disposing and routing the standard cells may be automatically performed by using a separate place-and-routing tool.

Verification of the layout as to whether or not a part violating certain requirements and/or expectations may be performed after the routing operation. Verification items may include design rule check (DRC) verifying that the layout fits to the design rule, electronical rule check (ERC) verifying that the layout is internally connected without any electrical break, layout vs. schematic (LVS) confirming that the layout is identical to a gate-level netlist, and the like. The routing and verification of the layout may be performed iteratively; alternatively or additionally, certain waivers may be allowed and the design rules may be adjusted during the routing and verification process.

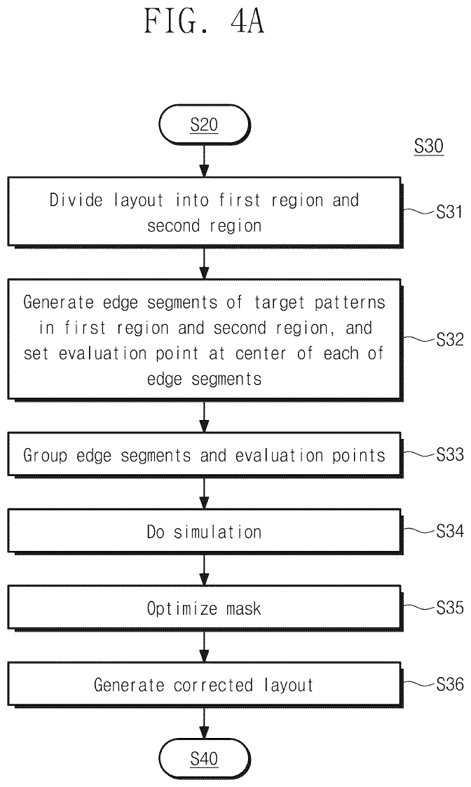

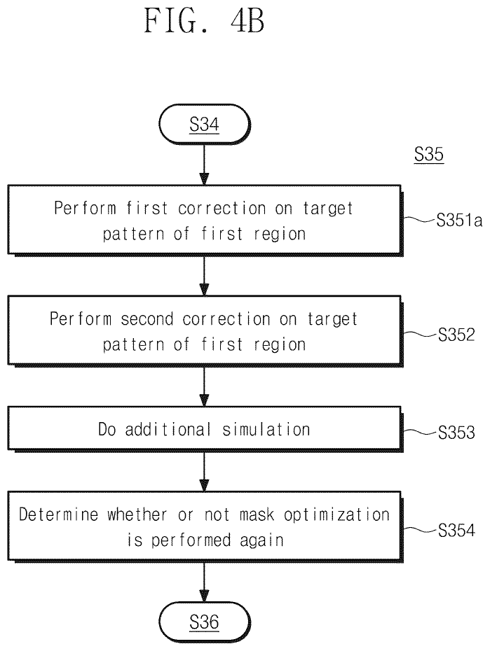

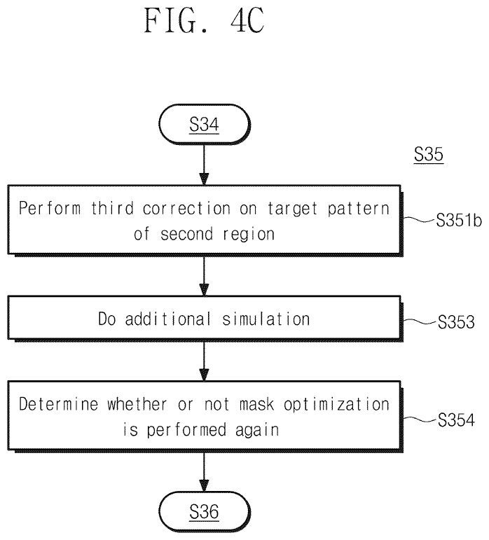

An operation (S30) of doing optical proximity correction (OPC) may be performed. The layout patterns obtained through designing the layout may be realized on the substrate by using a photolithography process. In this case, the optical proximity correction may be a technique for correcting or at least partly correcting a distortion phenomenon capable of occurring in the photolithography process. For example, the distortion phenomenon such as refraction, a process effect and/or the like occurring due to characteristics of light during exposing the layout pattern may be corrected through the optical proximity correction. Shapes and/or positions of the patterns in the designed layout may be changed (biased) during the optical proximity correction. In some examples, serifs may be added and/or removed from certain polygonal patterns in the layout. Alternatively or additionally in some examples, sub-resolution assist features (SRAFs) such as inriggers and/or outriggers may be added to the layout as part of the OPC. Description of the optical proximity correction will be made in more detail with reference to FIGS. 4A to 11.

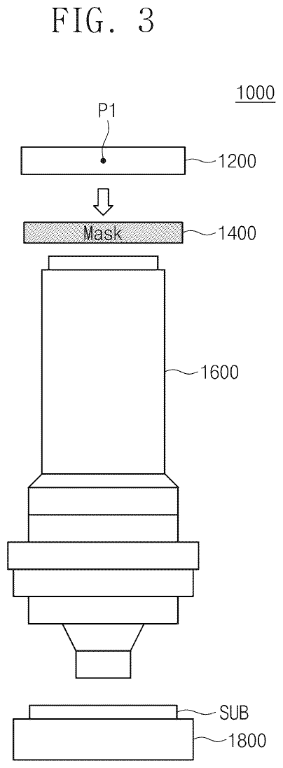

FIG. 3 is a conceptual diagram illustrating a photolithography system using a photomask manufactured according to some example embodiments.

Referring to FIG. 3, a photolithography system 1000 may include a light source 1200, a shrinkage projection device 1600 and a substrate stage 1800. In some example embodiments the photolithography system 1000 may include a photomask 1400 which may be removable. There may be a position in the photolithography system 1000 to accommodate different photomasks 1400. However, the photolithography system 1000 may further include components not illustrated in FIG. 3. For example, the photolithography system 1000 may further include a sensor used so as to measure a height and a slope of a surface of the substrate SUB.

The light source 1200 may emit light. The photomask 1400 may be irradiated with the light emitted from the light source 1200. For example, a lens may be provided between the light source 1200 and the photomask 1400 so as to control a focus of the light. The light source 1200 may include an ultraviolet light source (for example, a KrF light source having a wavelength of about 234 nm, an ArF light source having a wavelength of about 193 nm, or the like), or an extreme ultraviolet (EUV) light source. In some example embodiments, the light source 1200 may be the EUV light source. The light source 1200 may include one point light source P1, but example embodiments are not limited thereto. According to other example embodiments, the light source 1200 may include a plurality of point light sources.

The photomask 1400 may include image patterns so as to print (realize) the designed layout on the substrate SUB. The image patterns may be formed on the basis of the layout patterns obtained through the layout design and the optical proximity correction. The image patterns may be defined by a transparent region and an opaque region. The transparent region may be formed by etching a metal layer (for example, a chrome layer) on the photomask 1400. The transparent region may pass the light emitted from the light source 1200, and in some cases may include a transparent material such as glass. However, the opaque region may not allow light to pass and may block the light. In some example embodiments, the photomask 1400 may include a pellicle that covers and protects or at least partly protects the transparent region and the opaque region; example embodiments are not limited thereto.

The shrinkage projection device 1600 may be provided with the light passing the opaque region of the photomask 1400. The shrinkage projection device 1600 may match the patterns to be printed on the substrate SUB with the image patterns of the photomask 1400. The substrate SUB may be irradiated with the light passing the shrinkage projection device 1600. Accordingly, patterns corresponding to the image patterns of the photomask 1400 may be printed on or in the substrate SUB.

The substrate stage 1800 may support the substrate SUB. For example, the substrate SUB may include or may support a silicon wafer. The shrinkage projection device 1600 may include an aperture. The aperture may be used so as to increase a depth-of-focus of the ultraviolet light emitted from the light source 1200. For example, the aperture may include a dipole aperture or quadruple aperture. The shrinkage projection device 1600 may further include a lens so as to control a focus of the light.

Meanwhile, since integration of the semiconductor device increases, a distance between the image patterns of the photomask 1400 may be relatively very small. Interference and/or diffraction of light may occur due to such “proximity”, and thus a distorted pattern may be printed on the substrate SUB. When the distorted pattern is printed on the substrate SUB, the designed circuit may be abnormally operated.

Resolution enhancement technology (RET) may be used so as to prevent or reduce the impact from and/or the amount of distortion of the pattern. The optical proximity correction (S30, see FIG. 2) is an example of the resolution enhancement technology. According to the optical proximity correction, a degree of distortion such as the interference and the diffraction of the light may be predicted in advance by simulation of an OPC model. On the basis of a predicted result, the designed layout may be changed (biased). On the basis of the changed layout, the image patterns may be formed on the photomask 1400, and thus a desired pattern may be printed on the substrate SUB.

The layout of the semiconductor device may include a plurality of layers. For example, the optical proximity correction may be performed so as to adjust the layout of a single layer. In some example embodiments, the optical proximity correction may be independently performed on each of the plurality of layers. The semiconductor device may be formed by sequentially realizing the plurality of layers on the substrate through semiconductor processes. For example, the semiconductor device may include a plurality of stacked metal layers so as to realize a specific circuit.

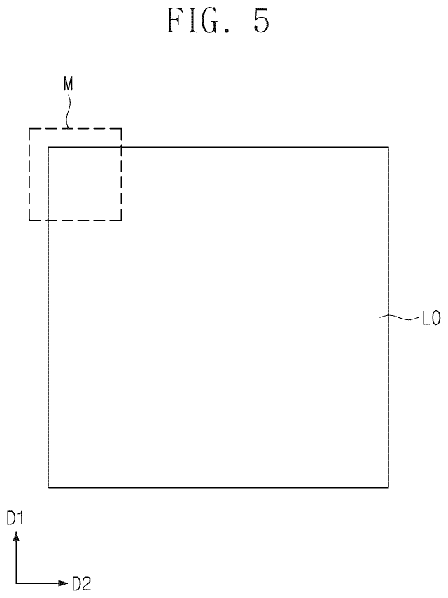

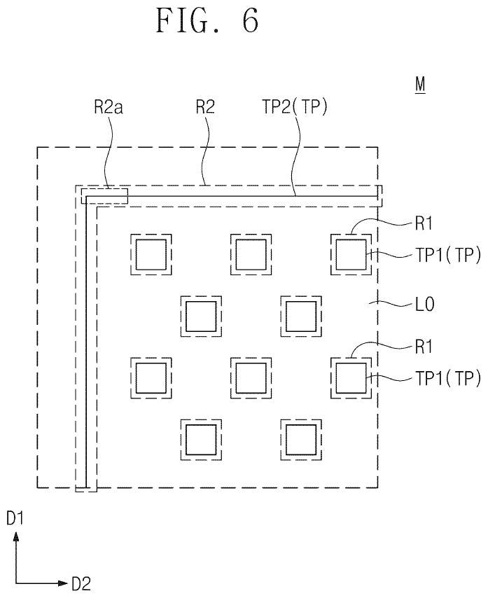

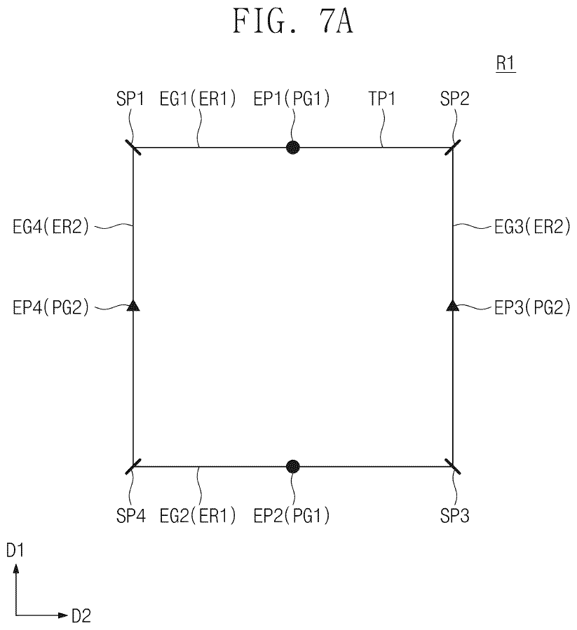

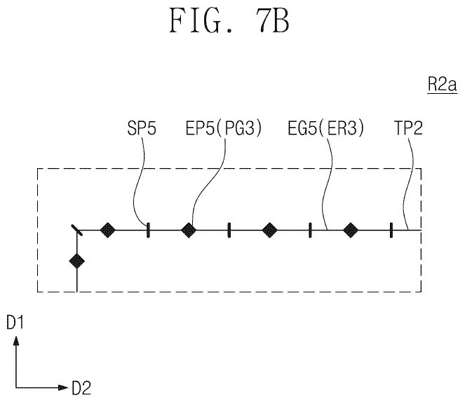

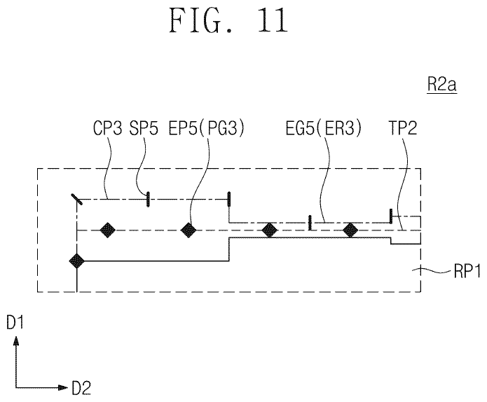

FIGS. 4A, 4B and 4C are flowcharts schematically illustrating specific operations of the optical proximity correction according to some example embodiments, respectively. FIGS. 5 to 11 are layout plan views for describing the optical proximity correction, respectively. Specifically, FIG. 6 is an enlarged view corresponding to M of FIG. 5. FIGS. 7A, 8A, 8B, 9A, 9B and 10 are enlarged views corresponding to R1 of FIG. 6, respectively. FIGS. 7B and 11 are enlarged views corresponding to R2a of FIG. 6, respectively. Hereinafter, the operation (S30) of doing the OPC described with reference to FIG. 2 will be described in detail.

Referring to FIGS. 4A and 5, the layout LO generated through the operation (S20) of designing a layout described with reference to FIG. 2 may be provided. The layout LO may be or may correspond to a single-layered layout. In some example embodiments, the layout LO may be formatted in a format such as but not limited to a graphics design system format, such as a GDSII stream format; example embodiments are not limited thereto.

Referring to FIGS. 4A and 6, the layout LO may be divided into a first region R1 and a second region R2 (S31). The first region R1 of the layout LO may be an inside surrounded an edge of the layout LO, and the second region R2 may be an edge of the layout LO.

The layout LO may include a target pattern TP. As referred to herein, the target pattern TP may mean or correspond to an ideal pattern which should be formed on the substrate SUB (see FIG. 3) through an exposure process using the photomask. As used herein, the layout LO may mean or correspond to a layout LO of a pattern formed on the photomask so as to form the target pattern TP. Due to characteristics of the exposure process, the photoresist pattern formed on the real substrate SUB (see FIG. 3) and the target pattern TP may have different shapes from each other.

The layout LO may include a first target pattern TP1 in the first region R1 and a second target pattern TP2 in the second region R2. The first region R1 of the layout LO may be provided in plurality. The first regions R1 of the layout LO may be disposed in a zigzag shape along the first direction D1 and the second direction D2. The first direction D1 and the second direction D2 may cross each other. The first target pattern TP1 may be provided in plurality. Each of the first target patterns TP1 may be located on the first region R1 of the layout LO. Accordingly, the first target patterns TP1 may be disposed in the zigzag shape along the first direction D1 or second direction D2.

The first region R1 of the layout LO may be defined as a 2-beam imaging region. Forming a photoresist pattern PRP (see FIG. 13) formed under the 2-beam imaging region may be affected by 0-th light and first light of the light used in the exposure process. Specifically, the 0-th light may be light passing a first image patterns IM1 (see FIG. 13) corresponding to the photoresist pattern PRP (see FIG. 13) among first image patterns IM1 (see FIG. 13). The first light may be light passing the first image patterns IM1 (see FIG. 13) adjacent to the first image patterns IM1 (see FIG. 13) corresponding to the photoresist pattern PRP (see FIG. 13) among the first image patterns IM1. The first light may pass the first image patterns IM1 (see FIG. 13), and may be diffracted to affect formation of the photoresist pattern PRP (see FIG. 13).

On the contrary, the second region R2 of the layout LO may not be the 2-beam imaging region. For example, in a region which is not the 2-beam imaging region, formation of the photoresist pattern PRP (see FIG. 13) formed under the corresponding region may be affected by an n-th light (for example, the 0-th light, the first light, . . . , the n-th light, and the like) of the light used in the exposure process.

Referring to FIGS. 4A, 7A and 7B, edge segments of each of the first target pattern TP1 and the second target pattern TP2 may be generated, and an evaluation point may be set, for example, at the center of each of the edge segments (S32).

Generating the edge segments of the first target pattern TP1 may include setting first to fourth partition points SP1 to SP4 on vertexes of the first target pattern TP1 and generating the edge segments between the first to fourth partition points SP1 to SP4. For examples, the first target pattern TP1 may have a first edge segment EG1 between the first and second partition points SP1 and SP2. The first target pattern TP1 may have a second edge segment EG2 between the third and fourth partition points SP3 and SP4. The first target pattern TP1 may have a third edge segment EG3 between the second and third partition points SP2 and SP3. The first target pattern TP1 may have a fourth edge segment EG4 between the first and fourth partition points SP1 and SP4. The first and second edge segments EG1 and EG2 may face each other. The third and fourth edge segments EG3 and EG4 may face each other. Each of the edge segments EG1 and EG2 may extend orthogonally to each of the edge segments EG3 and EG4; however, example embodiments are not limited thereto, and in some cases, edge segments EG1 and EG2 may extend in a direction not orthogonal to, e.g., crossing, e.g., crossing at 45 degrees, a direction in which edge segments EG3 and EG4 extend.

Setting the evaluation point at the center of each of the first to fourth edge segments EG1, EG2, EG3 and EG4 of the first target pattern TP1 may include setting a first evaluation point EP1 at the center of the first edge segment EG1, setting a second evaluation point EP2 at the center of the second edge segment EG2, setting a third evaluation point EP3 at the center of the third edge segment EG3, and setting a fourth evaluation point EP4 at the center of the fourth edge segment EG4.

Generating the edge segments of the second target pattern TP2 may include setting fifth partition points SP5 disposed, on the second target pattern TP2, spaced apart from each other at a constant interval, and generating fifth edge segments EG5 therebetween. Setting the evaluation point at the center of each of the fifth edge segments EG5 of the second target pattern TP2 may include setting a fifth evaluation point EP5 at the center of each of the fifth edge segments EG5.

Thereafter, an operation (S33) of grouping the evaluation points and the edge segments described above may be performed. For example, the first and second edge segments EG1 and EG2 of the first target pattern TP1 may be grouped as a first edge group ER1. The third and fourth edge segments EG3 and EG4 of the first target pattern TP1 may be grouped as a second edge group ER2. The fifth edge segment EG5 of the second target pattern TP2 may be grouped as a third edge group ER3.

In addition, the first and second evaluation points EP1 and EP2 of the first target pattern TP1 may be grouped as a first point group PG1. The third and fourth evaluation point EP3 and EP4 of the first target pattern TP1 may be grouped as a second point group PG2. The fifth evaluation points EP5 of the second target pattern TP2 may be grouped as a third point group PG3.

When an operation (S35) of optimizing or improving a mask to be described later is performed, the OPC procedure may be performed on the grouped edge groups. For example, when the OPC procedure is performed on the grouped edge groups, the grouped point group may be utilized. Detailed description thereof will be described later.

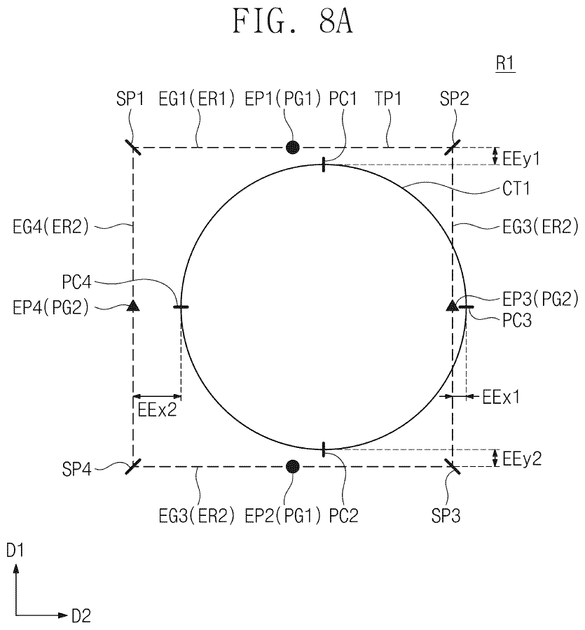

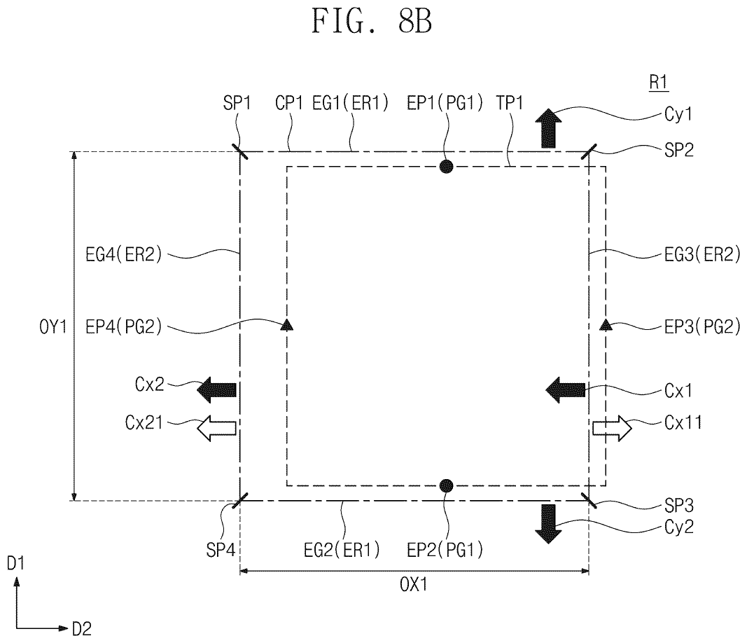

Referring to FIGS. 4A and 8A, an operation (S34) of doing simulation, e.g., a photolithographic simulation, by inputting, to an OPC model, a data of the first target pattern TP1 of the layout LO may be performed. Accordingly, a contour of the first target pattern TP1 may be extracted. As referred to herein, the contour may mean or correspond to a real photoresist pattern formed on the substrate SUB during the exposure process through the photomask manufactured on the basis of the layout LO. Accordingly, making the contour as similar to a shape of the first target pattern TP1 as possible may correspond to a purpose of the OPC technique.

The contour of the first target pattern TP1 generated after the operation (S34) of doing simulation is defined as a first contour CT1. The first contour CT1 may have a point thereon, thereunder, and on both sides thereof. Specifically, the first contour CT1 may have a first point PC1 adjacent to the first edge segment EG1, a second point PC2 adjacent to the second edge segment EG2, a third point PC3 adjacent to the third edge segment EG3, and a fourth point PC4 adjacent to the fourth edge segment EG4.

Thereafter, an operation (S35) of improving or optimizing a mask may be performed, and will be described in detail later.

Referring to FIGS. 4A, 4B, 8A and 8B, the operation (S35) of improving or optimizing a mask on the first target pattern TP1 may be performed. The operation (S35) of improving or optimizing a mask on the first target pattern TP1 may include an operation (S351a) of performing a first correction on the first target pattern TP1, an operation (S352) of performing a second correction on the first target pattern TP1, an operation (S353) of doing additional simulation, and an operation (S354) of determining whether or not mask optimization is to be performed again.

First, the operation (S351a) of performing a first correction on the first target pattern TP1 will be described. The operation (S351a) of performing a first correction on the first target pattern TP1 may include an operation of selecting an edge group that performs the first correction, an operation of calculating an edge placement error (EPE) between the selected edge group and the first contour CT1, and an operation of moving the selected edge group on the basis of the EPE.

The edge group that performs the first correction may be selected. As described herein, the first correction is performed on the first edge group ER1 first, but example embodiments are not limited thereto. Alternatively, the first correction may be performed on the second edge group ER2 first. For example, the first correction is performed on the first edge group ER1, and then the second correction is performed on the second edge group ER2. On the contrary, the first correction is performed on the second edge group ER2, and then the second correction is performed on the first edge group ER1.

After the operation of selecting the first edge group ER1, the operation of calculating the edge placement error (EPE) between the first edge group ER1 and the first contour CT1 may be performed. As described herein, the EPE may mean or may correspond to a difference (or distance) between the contour and the edge segment of the target pattern. The EPE between the first point PC1 of the first contour CT1 and the first edge segment EG1 may be calculated by generating a first error vector EEy1 at the first point PC1 of the first contour CT1. A size of the first error vector Eey1 may be a distance between the first edge segment EG1 and the first point PC1 of the first contour CT1. A direction of the first error vector Eey1 may be vertical to a tangent of the first point PC1 of the first contour CT1, and may face the first edge segment EG1 (for example, in the first direction D1).

The EPE between the second point PC2 of the first contour CT1 and the second edge segment EG2 may be calculated by generating a second error vector Eey2 at the second point PC2 of the first contour CT1. A size of the second error vector Eey2 may be a distance between the second edge segment EG2 and the second point PC2 of the first contour CT1. A direction of the second error vector EEy2 may be vertical to a tangent of the second point PC2 of the first contour CT1, and may face the second edge segment EG2 (for example, in an opposite direction of the first direction D1). The size and/or the direction of each of the first error vector EEy1 and the second error vector EEy2 are not limited to the values above, and may be changed depending on a size and a position of the first contour CT1.

An operation (Cy1) of moving the first edge segment (EG1) on the basis of the first error vector EEy1 may be performed. An operation (Cy2) of moving the second edge segment (EG2) on the basis of the second error vector EEy2 may be performed.

Thereafter, the operation (S352) of performing a second correction on the second edge group ER2 may be performed. First, the second correction may include moving the second edge group ER2 by calculating the EPE between the second edge group ER2 and the first contour CT1. The EPE between the third edge segment EG3 and the third point PC3 of the first contour CT1 may be calculated by generating a third error vector EEx1 at the third point PC3 of the first contour CT1. A size of the third error vector EEx1 may be a distance between the third point PC3 of the first contour CT1 and the third edge segment EG3. A direction of the third error vector EEx1 may be vertical to a tangent of the third point PC3 of the first contour CT1, and may face the third edge segment EG3 (for example, in the second direction D2).

The EPE between the fourth edge segment EG4 and the fourth point PC4 of the first contour CT1 may be calculated by generating a fourth error vector EEx2 at the fourth point PC4 of the first contour CT1. A size of the fourth error vector EEx2 may be a distance between the fourth point PC4 of the first contour CT1 and the fourth edge segment EG4. A direction of the fourth error vector EEx2 may be vertical to a tangent of the fourth point PC4 of the first contour CT1, and may face the fourth edge segment EG4 (for example, in an opposite direction of the second direction D2).

Thereafter, an operation (Cx1) of moving the third edge segment EG3 and an operation (Cx2) of moving the fourth edge segment EG4 on the basis of a sum of (e.g., a vector sum of) the third error vector EEx1 and the fourth error vector EEx2 may be performed. Directions and distances where the third edge segment EG3 and the fourth edge segment EG4 move may be substantially the same as each other.

Thereafter, in the second correction, an operation of additionally moving each of the third and fourth edge segments EG3 and EG4 may be performed so as to fit a long-short ratio (for example, the long-short ratio of a first correction pattern CP1 to be described later) between the first edge group ER1 moving through correction and the second edge group ER2 moving through correction. As described herein, the long-short ratio of a pattern may be defined as a value that divides a width in the first direction D1 of the pattern by a width in the second direction D2 of the pattern. The first long-short ratio may be a value set in advance, for example, by a user. For example, the first long-short ratio may be substantially the same as a long-short ratio of the first target pattern TP1. For example, the first long-short ratio may be a value of about 0.9 to about 1.1.

According to the diagrams, in order to fit the first long-short ratio, an operation (Cx11) of additionally moving the third edge segment EG3 in the second direction D2 may be performed, and an operation (Cx21) of additionally moving the fourth edge segment EG4 in an opposite direction of the second direction D2 may be performed, but example embodiments are not limited thereto. A direction of moving each of the third edge segment EG3 and the fourth edge segment EG4 so as to fit the first long-short-ratio may be changed depending on a moving direction and distance of each of the first and second edge segments EG1 and EG2 in the first correction.

The first correction pattern CP1 of the first contour CT1 may be finally generated by sequentially performing the first correction and the second correction described above. The long-short ratio (a ratio of the first width OX1 to the second width OY1) of the first correction pattern CP1 may be the first long-short ratio.

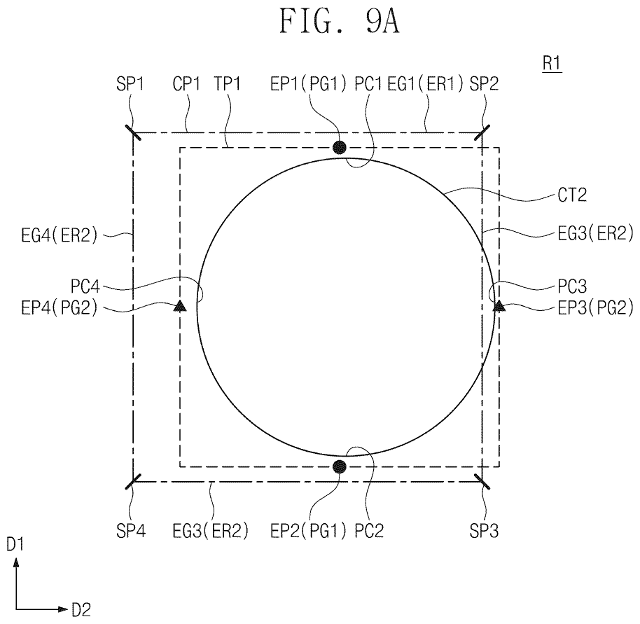

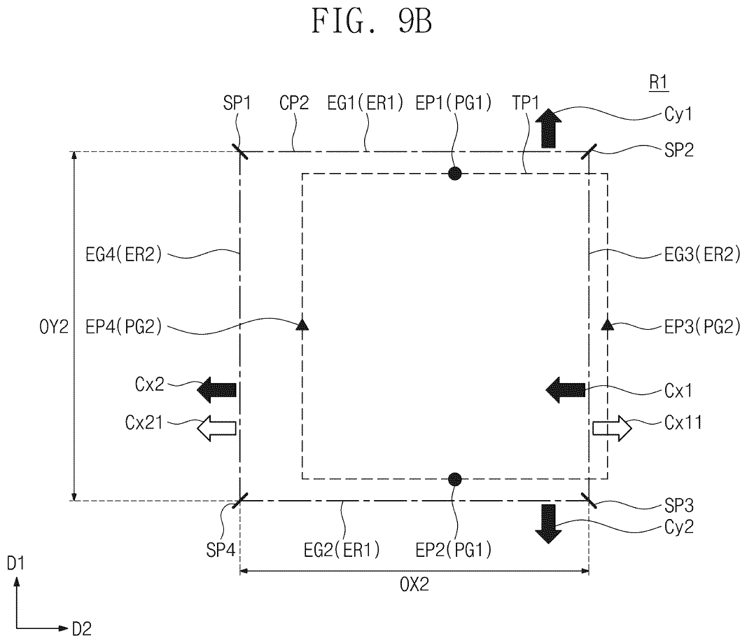

Referring to FIGS. 4A, 4B, 9A and 9B, the operation (S353) of doing additional simulation may be performed by inputting a data on the first correction pattern CP1 to the OPC model. Accordingly, a second contour CT2 on the first correction pattern CP1 may be extracted.

A long-short ratio of the second contour CT2 and the long-short ratio of the first contour CT1 (see FIG. 8A) may be substantially the same as each other regardless of the OPC technique of the first target pattern TP1, a size and/or shape of the first correction pattern CP1 generated according to the OPC technique, and the like. As described herein, the long-short ratio of the contours CT1 and CT2 means or corresponds to a ratio of a distance between the third point PC3 and the fourth point PC4 to a distance between the first point PC1 and the second point PC2. The second contour CT2 may become greater or smaller than a size of the first contour CT1 (see FIG. 8A), but the long-short-ratio thereof may be substantially the same as each other. This feature of the 2-beam imaging region (for example, the first region R1 of the layout LO) is due to a relation between the contour and the target pattern adjacent to the target pattern corresponding to the contour. Specifically, forming the contour may be affected by first light passing the target patterns adjacent to the target pattern corresponding to the contour. In this case, when the contour is formed, the first light may not affect a change in the long-short-ratio of the contour. Accordingly, although the long-short-ratio of the correction pattern generated through the OPC technique, the long-short-ratio of the contour may be continuously maintained.

Thereafter, the operation (S354) of determining whether or not mask optimization is to be performed again may be performed. The operation (S354) may include calculating the EPE between each of the first to fourth evaluation points EP1, EP2, EP3 and EP4 and the first to fourth points PC1, PC2, PC3 and PC4 of the second contour CT2, and determining whether or not the EPE exceeds a value (e.g., a predetermined value) required by or expected of the OPC. Specifically, a fifth error vector between the first evaluation point EP1 and the tangent of the first point PC1 of the second contour CT2 may be calculated to calculate the EPE therebetween. A sixth error vector between the second evaluation point EP2 and the tangent of the second point PC2 of the second contour CT2 may be calculated to calculate the EPE therebetween. A seventh error vector between the third evaluation point EP3 and the tangent of the third point PC3 of the second contour CT2 may be calculated to calculate the EPE therebetween. An eighth error vector between the fourth evaluation point EP4 and the tangent of the fourth point PC4 of the second contour CT2 may be calculated to calculate the EPE therebetween.

When the calculated EPE exceeds a predetermined value required by the OPC, the operation (S35) of optimizing a mask on the first target pattern TP1 may be performed again. When the calculated EPE is equal to or less than the value required by or expected of the OPC, the operation (S35) of optimizing a mask on the first target pattern TP1 may be terminated.

As described herein, assuming that the calculated EPE exceeds the value expected of the OPC, the operation (S35) of optimizing a mask on the first target pattern TP1 is performed again. The operation (S35) of improving or optimizing a mask performed again may be the same as the operation (S35) of improving or optimizing a mask described above; however, example embodiments are not limited thereto.

The first correction on the first edge group ER1 of the first correction pattern CP1 may be performed again. The first correction on the first edge group ER1 of the first correction pattern CP1 may be the same as/similar to the first correction described with reference to FIGS. 4A, 4B, 8A and 8B. For example, the operation (Cy1) of moving the first edge segment EG1 on the basis of the fifth error vector between the first evaluation point EP1 and the tangent of the first point PC1 of the second contour CT2 may be performed. The operation (Cy2) of moving the second edge segment EG2 on the basis of the sixth error vector, between the second evaluation point EP2 and the tangent of the second point PC2 of the second contour CT2, calculated above may be performed.

Thereafter, the second correction on the second edge group ER2 of the first correction pattern CP1 may be performed again. The second correction may be the same as/similar to the second correction described with reference to FIGS. 4A, 4B, 8A and 8B. For example, the operation (Cx1) of moving the third edge segment EG3 and the operation (Cx2) of moving the fourth edge segment EG4 on the basis of the sum of the seventh error vector and the eighth error vector may be performed. Directions and distances where the third edge segment EG3 and the fourth edge segment EG4 move may be substantially the same as each other.

Thereafter, an operation of additionally moving each of the third and fourth edge segments EG3 and EG4 may be performed so as to fit the long-short-ratio between the first edge group ER1 moving through correction and the second edge group ER2 moving through correction. For example, according to the diagrams, the operation (Cx11) of additionally moving the third edge segment EG3 in the second direction D2, and the operation (Cx21) of additionally moving the fourth edge segment EG4 in an opposite direction of the second direction D2 may be performed so as to fit the first long-short-ratio, but example embodiments are not limited thereto.

The first correction and the second correction, performed again, described above may be sequentially performed to finally generate the second correction pattern CP2 on the second contour CT2. A long-short-ratio (e.g., a ratio of the third width OX2 to the fourth width OY2) of the second correction pattern CP2 may be the first long-short-ratio.

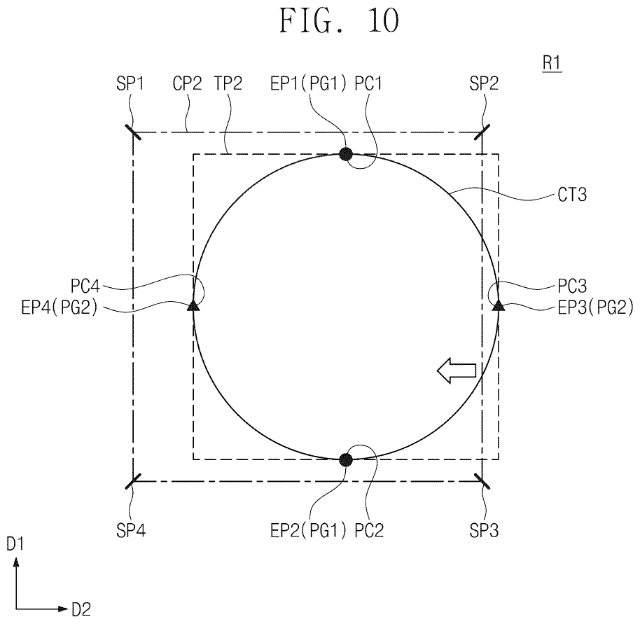

Referring to FIGS. 4A, 4B and 10, the operation (S353) of doing additional simulation by inputting a data on the second correction pattern CP2 to the OPC model may be performed. Accordingly, a third contour CT3 on the second correction pattern CP2 may be extracted. A long-short-ratio of the third contour CT3 may be substantially be the same as the long-short-ratio of each of the first contour CT1 (see FIG. 8A) and the second contour CT2 (see FIG. 9A). The reason why the long-short-ratios thereof are the same as each other was described above.

Thereafter, the operation (S354) of determining whether or not mask improvement or optimization is to be performed again may be performed again. When the EPE between each of the first to fourth evaluation points EP1, EP2, EP3 and EP4 and each of the first to fourth points PC1, PC2, PC3 and PC4 of the second contour CT2 is equal to less than a predetermined value required by the OPC, the operation (S35) of optimizing a mask on the first target pattern TP1 may be terminated. As described herein, assuming that the calculated EPE is equal to or less than the predetermined value required by the OPC, the operation (S35) of optimizing a mask on the first target pattern TP1 may be terminated.

Referring to FIGS. 4A, 4C and 11, the operation (S34) of doing simulation by inputting a data on the second target pattern TP2 of the layout LO to the OPC model may be performed. Accordingly, a first real pattern RP1 on the second target pattern TP2 may be extracted. As described herein, a real pattern may mean or may correspond to a real photoresist pattern formed on the substrate SUB during the exposure process through the photomask manufactured on the basis of the layout LO. Accordingly, making the real pattern as similar to a shape of the second target pattern TP2 as possible may correspond to the purpose of the OPC technique.

The operation (S35) of optimizing a mask on the second target pattern TP2 may be performed. The operation (S35) of optimizing a mask on the second target pattern TP2 may include an operation (S351b) of performing a third correction on the second target pattern TP2, the operation (S353) of doing additional simulation, and the operation (S354) of determining whether or not mask optimization or improvement is to be performed again.

The operation (S351b) of performing the third correction may include an operation of calculating the EPE between the third edge group ER3 of FIG. 7B and the first real pattern RP1 of FIG. 11, and an operation of moving the third edge group ER3 on the basis of the EPE. The operation of calculating the EPE may be the same as/similar to the operation of calculating the EPE between the first edge group ER1 and the first contour CT1 describe above. The third correction pattern CP3 on the first real pattern RP1 may be generated through the operation (S351b) of performing the third correction.

Thereafter, the operation (S353) of doing additional simulation may be performed by inputting a data on the third correction pattern CP3 on the first real pattern RP1 to the OPC model. Accordingly, the second real pattern (not shown) on the third correction pattern CP3 may be extracted.

Thereafter, the operation (S353) of determining whether or not mask improvement or optimization is to be performed again may be performed. The operation (S354) may include an operation of calculating the EPE between each of the fifth evaluation points EP5 and the second real pattern, and determining whether or not the EPE exceeds a predetermined value required by the OPC. As described herein, assuming that the calculated EPE is equal to or less than the value required by or expected of the OPC, the operation (S35) of optimizing a mask on the second target pattern TP2 may be terminated.

Referring back to FIGS. 4A to 11, an operation (S36) of generating the layout LO corrected through the final OPC patterns obtained through the operation (S35) of optimizing or improving a mask on each of the first target pattern TP1 and the second target pattern TP2 may be performed.

According to some example embodiments, when the OPC procedure on the first target pattern TP1 of the first region R1 of the layout LO is performed, the OPC (for example, the first correction) on the first edge group ER1 and the OPC (for example, the second correction) on the second edge group ER2 may be performed in different methods. For example, the OPC on the first edge group ER1 may include an operation of moving the first edge group ER1 on the basis of error vectors between the first edge group ER1 (or the first point group PG1) and the contour. The OPC on the second edge group ER2 may include an operation of moving the second edge group ER2 on the basis of a sum of error vector between the second edge group ER2 (or the second point group PG2) and the contour, and an operation of additionally moving the second edge group ER2 so as to fit to the long-short-ratio of the correction pattern set in advance, e.g., by a user.

When the OPC according to some example embodiments is not performed, and the OPC on the first edge group ER1 is performed on the second edge group ER2, the long-short-ratio of the correction pattern may become too greater or smaller. Although the third edge segment EG3 and the fourth edge segment EG4 are independently moved so as to fit to each of the third point PC3 and the fourth point PC4 of the first contour CT1 to each of the third evaluation point EP3 and the fourth evaluation point EP4 of the first target pattern TP1, the long-short-ratio of the second contour CT2 generated through simulation may be substantially the same as the long-short-ratio of the first contour CT1. Although the third edge segment EG3 and the fourth edge segment EG4 are independently moved so as to fit each of the third point PC3 and the fourth point PC4 of the second contour CT2 to each of the third evaluation point EP3 and the fourth evaluation point EP4 again, the long-short-ratio of the third contour CT3 generated through simulation may be substantially the same as the long-short-ratio of the first contour CT1. As a result, through the subsequent OPC procedures, each of the third edge segment EG3 and the fourth edge segment EG4 may move continuously in a certain direction, and thus the long-short-ratio of the correction pattern may become too greater or smaller, as described above. Accordingly, the long-short-ratio of the first image patterns IM1 (see FIG. 12) to be described later may become too greater or smaller. Accordingly, distribution of the first image patterns IM1 (see FIG. 12) to be described later, and distribution of the photoresist patterns PRP to be described later may be deteriorated, and thus reliability of the semiconductor device may be reduced.

According to some example embodiments, the limitation above may be solved or at least improved upon by performing the second correction on the second edge group ER2 described above. For example, the second point group PG2 and the contour may be targeted through the operation of moving the second edge group ER2 on the basis of the sum of the error vector described above. Simultaneously, a phenomenon that the long-short-ratio of the correction pattern becomes too greater or smaller may be prevented or reduced in likelihood of occurrence through the operation of additionally moving the second edge group ER2 so as to fit the long-short-ratio of the correction pattern set in advance by a user. As a result, the distribution of the first image patterns IM1 (see FIG. 12) to be described later, and the distribution of the photoresist patterns PRP may be improved, and thus the reliability of the semiconductor device may be improved.

FIG. 12 is a plan view illustrating a photomask according to some example embodiments.

Referring to FIGS. 2 and 12, an operation (S40) of manufacturing the photomask 1400 on the basis of final OPC patterns of FIGS. 10 and 11 may be performed. The photomask 1400 may include image patterns IM. The first image pattern IM1 among the image patterns IM may be formed along the determined second correction pattern CP2 described above. The second image pattern IM2 among the image patterns IM may be formed along the third correction patterns CP3 described above.

The photomask 1400 may include an opaque region and a transparent region. The opaque region may not pass light and may block the light. Meanwhile, the transparent region may pass the light emitted from the light source 1200. The substrate SUB of FIG. 3 may be irradiated with the light passing the photomask 1400. For example, the image patterns IM may be the transparent region of the photomask 1400 in a case of the photolithography process using a negative photoresist; alternatively, the image patterns IM may be the opaque region of the photomask in a case of the photolithography process using a positive resist.

FIG. 13 is a conceptual diagram illustrating that the photoresist patterns are formed on the substrate using the photomask of FIG. 12.

Referring to FIG. 13, the light source 1200 of FIG. 3 may emit light to the photomask 1400. The emitted light may pass the transparent region of the image patterns IM, and the photoresist layer PRL on the substrate SUB may be irradiated with the emitted light (the exposure process). The region, irradiated with the light, of the photoresist layer PRL may be the photoresist pattern PRP. The photoresist pattern PRP may be formed having the same shape and size as the third contour CT3 described above. In addition, the edge part of the photoresist layer PRL may be formed having the same shape and size as the second real pattern described above.

The photoresist patterns PRP may remain, and a rest of the photoresist layer PRL may be removed by performing the subsequent develop process. An etching target layer TGL on the substrate SUB may be patterned, e.g., etched with an anisotropic and/or isotropic etching process, by using the remaining photoresist patterns PRP as etching masks. Accordingly, target patterns may be realized on the substrate SUB. As a result, the semiconductor device may be manufactured by realizing the target patterns of each layer in the above method (S50, see FIG. 2).

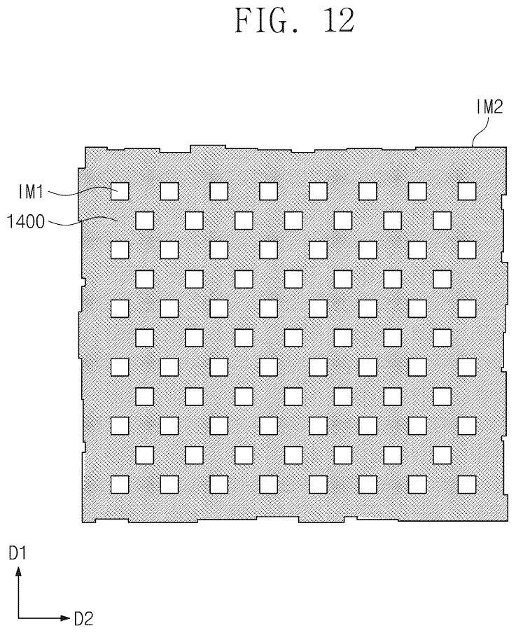

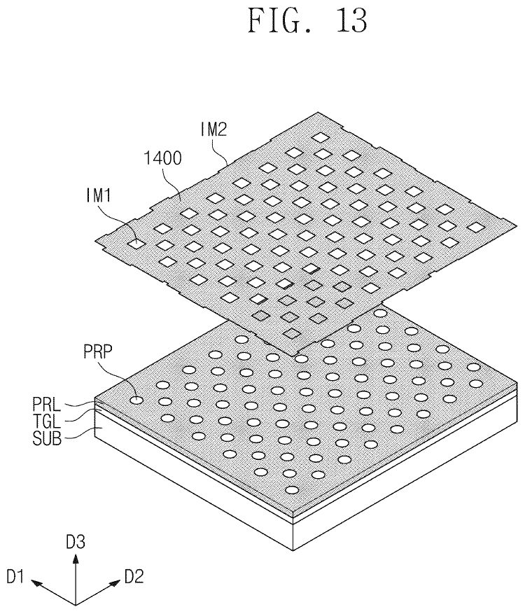

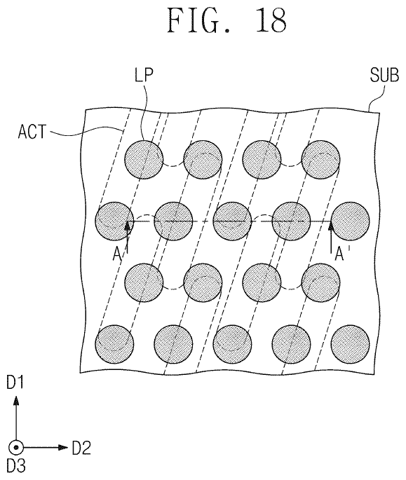

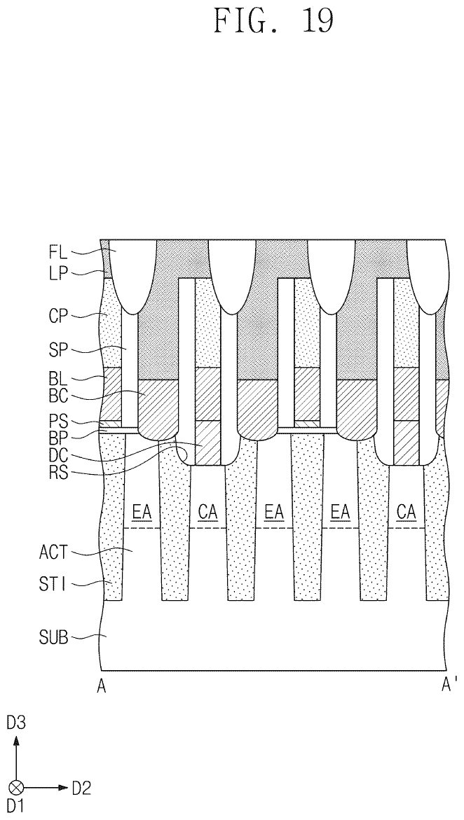

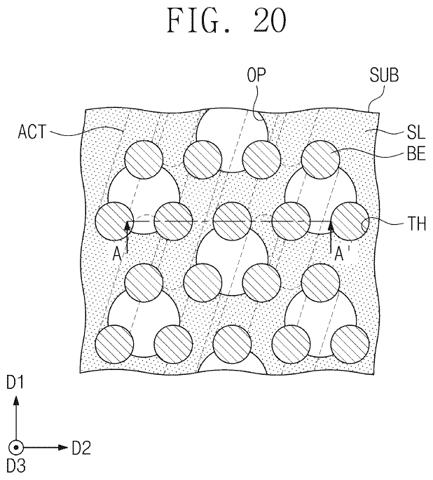

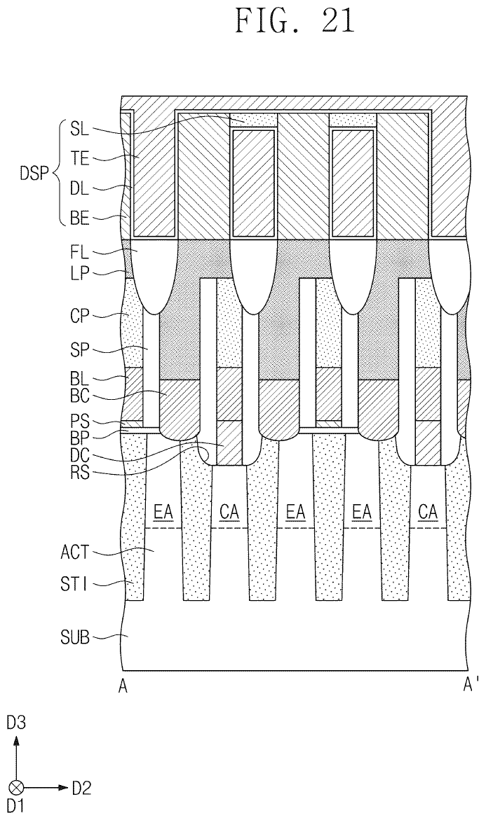

FIGS. 14 to 21 are diagrams illustrating a method for manufacturing a semiconductor device according to some example embodiments. Specifically, FIGS. 14, 16, 18 and 20 are plan views illustrating the method for manufacturing the semiconductor device according to some example embodiments. FIGS. 15, 17, 19, and 21 are cross-sectional views corresponding to line A-A′ of each of FIGS. 14, 16, 18 and 20.

Referring to FIGS. 14 and 15, active patterns ACT may be formed by patterning an upper portion of the substrate SUB. Each of the active patterns ACT may extend in a direction parallel to an upper surface of the substrate SUB. The active patterns ACT may be arranged spaced apart from each other along the first direction D1 and the second direction D2.

The active patterns ACT may be realized by using the photolithography process. At least one photomask used in the photolithography process for realizing the active patterns ACT may be manufactured through the OPC technique according to example embodiments described with reference to FIGS. 4 to 11.

According to some example embodiments, a patterning process for forming the active patterns ACT may include an EUV lithography process. The EUV lithography process may include the exposure and develop processes using EUV with which the photoresist layer is irradiated. For example, the photoresist layer may be an organic photoresist containing an organic polymer such as polyhydroxystyrene. The organic photoresist may further include a photosensitive compound that reacts with the EUV. The organic photoresist may further include a material having EUV absorption rate such as one or more of an organometallic material, an iodine-containing material, or a fluorine-containing material. For another example, the photoresist layer may be or may include an inorganic photoresist containing an inorganic material such as tin oxide.

The photoresist layer may be formed having a relatively small thickness. The photoresist patterns may be formed by developing the photoresist layer exposed to the EUV. On a plan view, the photoresist patterns may have one or more shapes, such as one or more of a shape of a line extending in one direction, an island, a zigzag, a honeycomb, or a circle, but example embodiments are not limited thereto.

At least one mask layer stacked under the photoresist patterns may be patterned, using the photoresist patterns as etching masks, to form mask patterns. A target layer may be patterned, using the mask patterns as the etching masks, to form targeted patterns on a wafer.

For example, the active patterns ACT realized in the EUV lithography process according to some example embodiments may have a minimum pitch of about 45 nm or less. For example, the EUV lithography process may be performed to realize a sophisticated and fine active patterns ACT with one photomask.

A trench, such as a shallow trench, may be formed between the active patterns ACT, and an element isolation layer STI that fills the inside of the trench may be formed.

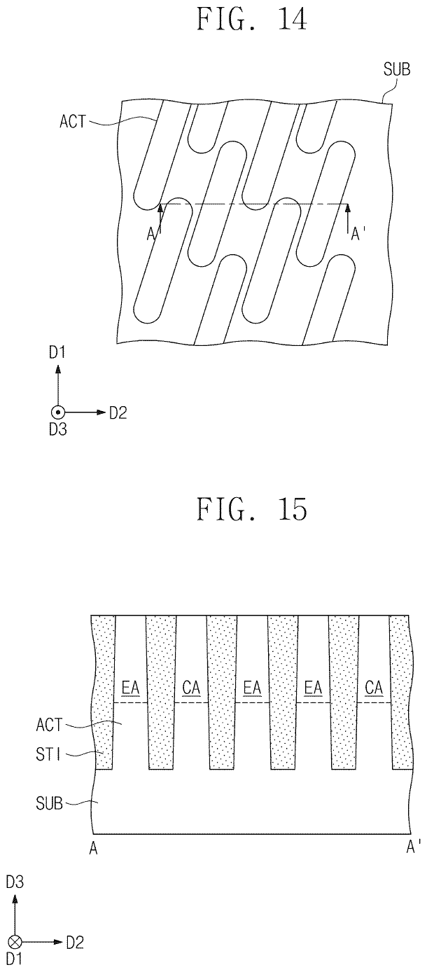

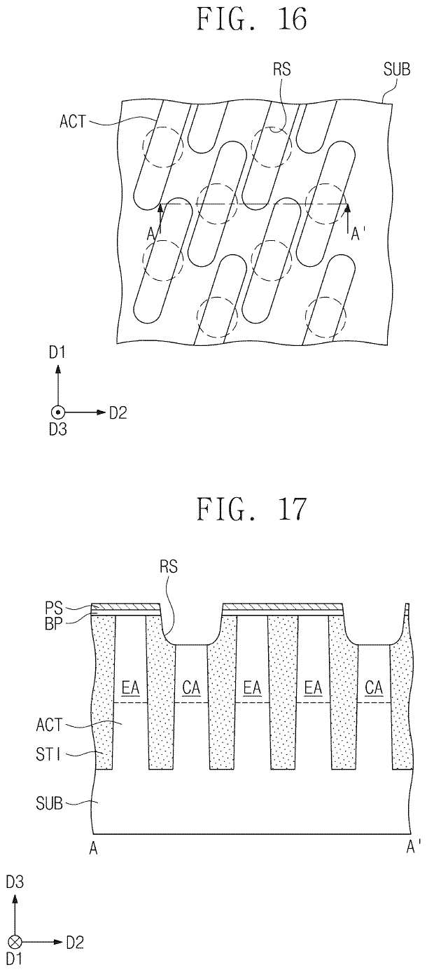

Referring to FIGS. 16 and 17, although not shown, a word line (not shown) crossing each of the active patterns ACT may be formed. Forming the word line may include sequentially forming a gate dielectric pattern (not shown), a gate electrode (not shown), and a gate capping pattern (not shown), with one or more processes such as one or more of an oxidation process, a deposition process such as one or more of a chemical vapor deposition (CVD) process, an atomic layer deposition (ALD) process, or a physical vapor deposition (PVD) process, and a chemical mechanical planarization (CMP) process. Example embodiments are not limited thereto.

A buffer pattern BP and a polysilicon pattern PS may be sequentially formed on the substrate SUB. The buffer pattern BP and the polysilicon pattern PS may be formed so as to cover the active patterns ACT and the element isolation layer STI.

A recess region RS may be formed on a central portion CA of each of the active patterns ACT. The buffer pattern BP and the polysilicon pattern PS may be partially removed in a process of forming the recess region RS. The recess region RS may be realized using the photolithography process. At least one photomask used in the photolithography process for realizing the recess region RS may be manufactured through the OPC technique according to some example embodiments described with reference to FIGS. 4A to 11 above.

Thereafter, bit line structures respectively extending along the first direction D1, and disposed spaced apart from each other in the second direction D2 may be formed on the central portion EA of the active pattern ACT. Each of the bit line structures may include a bit line contact DC, a bit line BL and a bit line capping pattern CP sequentially provided on the central portion EA of the active pattern ACT. Bit line spacers SP covering side surfaces of the bit line structures may be formed.

Storage node contacts BC may be formed between the bit line structures. Landing pads LP may be formed on the storage node contact BC. An upper portion of each of the landing pads LP may be shifted in the second direction D2. The upper portions of the landing pads LP may be realized using the photolithography process. At least one photomask used in the photolithography process for realizing the upper portions of the landing pads LP may be manufactured through the OPC technique according to some example embodiments described with reference to FIGS. 4A to 11 above.

A filling layer FL surrounding the upper portions of the landing pads LP may be formed. A data storage pattern DSP may be formed on the filling layer FL. The data storage pattern DSP may include a lower electrode BE on the upper portion of the landing pad LP, an upper electrode TE on the lower electrode BE, a dielectric layer DL between the lower electrode BE and the upper electrode TE, and a support layer SL connected to upper portions of the lower electrodes BE.

For example, forming the lower electrodes BE may include forming the support layer SL and a mold layer (not shown) on the filling layer FL, forming penetration holes TH by performing a process of partially removing each of the mold layer and the support layer SL, and forming the lower electrodes BE in the penetration holes TH.

When the penetration holes TH are formed, the photo lithography process may be utilized. At least one photomask used in the photolithography process for realizing the penetration holes TH may be manufactured through the OPC technique according to some example embodiments described above with reference to FIGS. 4A to 11.

For example, forming the dielectric layer DL and the upper electrode TE may include forming openings OP inside the support layer SL, removing the mold layer using the opening OP as a path, and forming the dielectric layer DL and the upper electrode TE in a region in which the mold layer is removed.

When the opening OP is formed, the photolithography process may be utilized. The photomask used in the photolithography process for realizing the openings OP may be manufactured through the OPC technique according to some example embodiments described with reference to FIGS. 4A to 11 above.

According to some example embodiments, when an OPC procedure on a target pattern of a first region of a layout is performed, an OPC technique on a first edge group and an OPC technique on a second edge group may be performed in different methods. For example, the OPC technique on the first edge group may include an operation of moving the first edge group on the basis of error vectors between the first edge group (or first point group) and a contour. The OPC technique on the second edge group may include an operation of calculating error vectors between the second edge group (or second point group) and the contour, and moving the second edge group on the basis of a sum of the error vectors, and an operation of additionally moving the second edge group so as to fit to a long-short-ratio of a correction pattern set in advance by a user.

When the OPC technique according to some example embodiments is not performed, and the OPC technique on the first edge group is performed on the second edge group, the long-short-ratio of the correction pattern may become too greater or smaller. Accordingly, the long-short-ratio of image patterns of the photomask may become too greater or smaller.

According to some example embodiments, the limitation above may be solved or improved upon by performing the OPC technique, on the second edge group, described above. For example, the contour and/or the second point group of the target pattern may be targeted through an operation of moving the second edge group on the basis of the sum of the error vector described above. Simultaneously, the phenomenon that the long-short-ratio of the correction pattern becomes too greater or smaller may be prevented or reduced in likelihood of occurrence through the operation of additionally moving the second edge group so as to fit the long-short-ratio of the correction pattern set in advance by the user. As a result, distribution of the image patterns of the photomask, and distribution of the photoresist patterns may be improved, thereby improving reliability of the semiconductor device.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

Although some example embodiments have been described, it is understood that inventive concepts should not be limited to these embodiments but various changes and modifications can be made by one of ordinary skill in the art within the spirit and scope of example embodiments as hereinafter claimed. Therefore, it should be understood that embodiments described above are examples in all respects and are not intended to be limiting. Furthermore example embodiments are not necessarily mutually exclusive with one another. For example, some example embodiments may include one or more features described with reference to one or more figures, and may also include one or more other features described with reference to one or more other figures.

What is claimed is:

1. A method for manufacturing a semiconductor device, the method comprising:
performing optical proximity correction on a layout to generate a corrected layout; and
forming a photoresist pattern on a substrate using a photomask manufactured with the corrected layout,
wherein the optical proximity correction includes,
generating a contour of a target pattern of the layout,
generating first to fourth error vectors between the contour and first to fourth edge segments of the target pattern, and
generating a correction pattern by sequentially performing a first correction and a second correction on the target pattern,
the first correction includes moving the first edge segment on the basis of the first error vector, and moving the second edge segment on the basis of the second error vector,
the second correction includes moving the third and fourth edge segments on the basis of a sum of the third error vector and the fourth error vector,
the first and second edge segments face each other, and
the third and fourth edge segments face each other.

2. The method of claim 1, further comprising:
setting a first long-short-ratio of the correction pattern,
wherein the second correction further includes additionally moving the third and fourth edge segments to fit the first long-short-ratio of the correction pattern.

3. The method of claim 1, wherein
the contour is a first contour,
the correction pattern is a first correction pattern, and
the method further comprises generating a second contour on the first correction pattern.

4. The method of claim 3, wherein the first contour has a same long-short-ratio as the second contour.

5. The method of claim 3, further comprising:
generating fifth to eighth error vectors between the target pattern and the second contour, after generating the second contour; and
generating a second correction pattern by sequentially performing a third correction and a fourth correction on the target pattern on the basis of the fifth to eighth error vectors.

6. The method of claim 5, wherein the first correction pattern has a same long-short-ratio as the second correction pattern.

7. The method of claim 1, wherein the third and fourth edge segments move the same distance in the same direction on the basis of the sum of the third error vector and the fourth error vector.

8. The method of claim 1, wherein the target pattern has a rectangular shape.

9. The method of claim 1, wherein each of the first and second edge segments is continuously connected to each of the third and fourth edge segments.

10. The method of claim 1, wherein
the target pattern comprises a plurality of target patterns in the layout, and
the target patterns are in a zigzag shape along one direction.

11. The method of claim 1, further comprising:
setting an evaluation point at the center of each of the first to fourth edge segments;
grouping, as a first point group, the evaluation point of the first edge segment and the evaluation point of the second edge segment; and
grouping, as a second point group, the evaluation point of the third edge segment and the evaluation point of the fourth edge segment.

12. The method of claim 1, further comprising:
dividing the layout into a first region and a second region,
wherein the target pattern is a first target pattern,
the second region is an edge region of the layout,
the first target pattern is provided in the first region, and
the layout further includes a second target pattern in the second region.

13. A method for manufacturing a semiconductor device, the method comprising:
performing optical proximity correction on a layout; and
forming a photoresist pattern on a substrate using a photomask manufactured with the corrected layout,
wherein the optical proximity correction includes,
generating a contour of a target pattern of the layout,
generating first to fourth error vectors between the contour and first to fourth edge segments of the target pattern,
generating a correction pattern by sequentially performing a first correction on each of the first and second edge segments facing each other, and a second correction on each of the third and fourth edge segments facing each other, and
setting a first long-short-ratio of the correction pattern, and
the second correction includes,
moving the third and fourth edge segments on the basis of a sum of the third error vector and the fourth error vector, and
fitting the first long-short-ratio of the correction pattern by additionally moving the third and fourth edge segments.

14. The method of claim 13, wherein the first correction comprises moving the first edge segment on the basis of the first error vector, and moving the second edge segment on the basis of the second error vector.

15. The method of claim 13, wherein the first long-short-ratio of the correction pattern is same as a long-short-ratio of the target pattern.

16. The method of claim 13, further comprising:
generating a second contour of the correction pattern,
wherein the contour is a first contour,
the correction pattern is a first correction pattern, and
the first contour has a same long-short-ratio as the second contour.

17. The method of claim 16, further comprising:
generating fifth to eighth error vectors between the target pattern and the second contour, after generating the second contour; and
generating a second correction pattern by sequentially performing a third correction and a fourth correction on the target pattern on the basis of the fifth to eighth error vectors,
wherein a long-short-ratio of the second correction pattern is same as the first long-short-ratio of the first correction pattern.

18. The method of claim 13, wherein
the target pattern comprises a plurality of target patterns in a layout, and
the target patterns are in a zigzag shape along one direction.

19. A method for manufacturing a semiconductor device, the method comprising:
generating a contour of a target pattern of a layout;
generating first to fourth error vectors between the contour and first to fourth edge segments of the target pattern;
generating a correction pattern by sequentially performing a first correction and a second correction on the target pattern;
manufacturing a photomask using the corrected layout including the correction pattern;
forming an etching target layer and a photoresist layer on a substrate;
forming photoresist patterns by exposing and developing the photoresist layer using the photomask; and
patterning the etching target layer using the photoresist patterns,
wherein the first correction includes moving the first edge segment on the basis of the first error vector, and moving the second edge segment facing the first edge segment on the basis of the second error vector, and
the second correction includes moving the third and fourth edge segments facing each other on the basis of a sum of the third error vector and the fourth error vector.

20. The method of claim 19, further comprising:
forming a mold layer and a support layer sequentially stacked on the substrate;
forming penetration holes penetrating each of the mold layer and the support layer; and
forming lower electrodes in the penetration holes,
wherein each of the photoresist patterns defines a mask associated with forming the penetration holes, and
each of the mold layer and the support layer is the etching target layer.
